(19) United States
(12) Patent Application Publication
(10) Pub. No.: US 2023/0420282 A1
(43) Pub. Date: Dec. 28, 2023

(54) WAFER PLACEMENT TABLE

(71) Applicant: NGK INSULATORS, LTD., Nagoya-City (JP)

(72) Inventors: Tatsuya KUNO, Nagoya-City (JP); Masaki ISHIKAWA, Handa-City (JP)

(73) Assignee: NGK INSULATORS, LTD., Nagoya-City (JP)

(21) Appl. No.: 18/345,094

(22) Filed: Jun. 30, 2023

Related U.S. Application Data
(63) Continuation of application No. PCT/JP2022/025790, filed on Jun. 28, 2022.

(51) Int. Cl. H01L 21/683; H01J 37/32

(52) U.S. Cl. CPC H01L 21/6833; H01J 2237/002; H01J 2237/2007; H01J 37/32724

(57) ABSTRACT

A wafer placement table includes a ceramic substrate that has a wafer placement surface on an upper surface, a first cooling substrate formed of a composite material of metal and ceramic or a low thermal expansion metal material, a metal joining layer that joins ceramic substrate and the first cooling substrate to each other, a second cooling substrate in which a refrigerant flow path is formed, a heat dissipation sheet disposed between the first cooling substrate and the second cooling substrate, a screw hole that opens in the lower surface of the first cooling substrate, a through hole that is provided at a position facing the screw hole and that extends through the second cooling substrate in an up-down direction, and a screw member that is inserted into the through hole from a lower surface of the second cooling substrate and that is screwed into the screw hole.

### BACKGROUND OF THE INVENTION

### 1. Field of the Invention

The present invention relates to a wafer placement table.

### BACKGROUND ART

### 2. Description of the Related Art

A wafer placement table of related art is known in which a ceramic substrate which is formed of alumina or the like and in which an electrostatic electrode is embedded and a cooling substrate formed of metal such as aluminum are joined to each other with a resin layer interposed therebetween (see, for example, PTL 1). With such a wafer placement table, influence of the difference in thermal expansion between the ceramic substrate and the cooling substrate can be reduced by the resin layer. Another wafer placement table is known in which a ceramic substrate and a cooling substrate provided with a refrigerant flow path therein are joined to each other with, instead of the resin layer, a metal joining layer (see, for example, PTLs 2 and 3). Since the thermal conductivity of the metal joining layer is higher than that of the resin layer, heat releasing capability required when a wafer is processed with high-power plasma can be achieved. In contrast, since the Young's modulus of the metal joining layer is greater than that of the resin layer, and a stress relaxation property of the metal joining layer is low, the metal joining layer is almost unable to reduce the influence of the difference in thermal expansion between the ceramic substrate and the cooling substrate. Thus, according to PTLs 2 and 3, as the material of the cooling substrate, a composite material of metal and ceramic that differs in the coefficient of thermal expansion from the ceramic substrate by a small amount is used.

### CITATION LIST

### Patent Literature

PTL 1: JP H4-287344 A
PTL 2: JP 5666748 B
PTL 3: JP 5666749 B

### SUMMARY OF THE INVENTION

However, the composite material of metal and ceramic is expensive compared to metal such as aluminum and the cost for forming the refrigerant flow path is high because the composite material of metal and ceramic is a difficult-to-process material. Thus, a manufacturing cost of the wafer placement table may increase in some cases. Furthermore, instead of using the composite material of metal and ceramic, it is conceivable to use a low thermal expansion metal material that differs in coefficient of thermal expansion from the ceramic substrate by a small amount. However, the low thermal expansion metal material is also expensive and the cost for forming the refrigerant flow path is also high because the low thermal expansion metal material is a difficult-to-process material. Thus, the manufacturing cost of the wafer placement table may increase in some cases.

The present invention is made to solve the above-described problem and is mainly aimed at reducing a manufacturing cost of a wafer placement table that highly efficiently cools a wafer.

[1] A wafer placement table according to the present invention includes a ceramic substrate that has a wafer placement surface on an upper surface thereof and that includes an electrode therein, a first cooling substrate formed of a composite material of metal and ceramic or a low thermal expansion metal material, a metal joining layer that joins a lower surface of the ceramic substrate and an upper surface of the first cooling substrate to each other, a second cooling substrate in which a refrigerant flow path is formed, a heat dissipation sheet disposed between a lower surface of the first cooling substrate and an upper surface of the second cooling substrate, a screw hole that opens in the lower surface of the first cooling substrate, a through hole that is provided at a position facing the screw hole and that extends through the second cooling substrate in an up-down direction, and a screw member that is inserted into the through hole from a lower surface of the second cooling substrate and that is screwed into the screw hole.

With this wafer placement table, efficiency of cooling the wafer is high due to joining of the ceramic substrate and the first cooling substrate to each other with the metal joining layer. In addition, the first cooling substrate and the second cooling substrate are fastened to each other with the screw member, and the heat dissipation sheet is disposed between the first cooling substrate and the second cooling substrate. The heat dissipation sheet is firmly in close contact with the first cooling substrate and the second cooling substrate by fastening the first cooling substrate and the second cooling substrate to each other with the screw member. Thus, heat of the first cooling substrate is quickly transferred to the second cooling substrate. Accordingly, the efficiency of cooling the wafer is high. Furthermore, the first cooling substrate and the second cooling substrate are joined to each other with the screw member. Thus, when the ceramic substrate degrades due to use of the wafer placement table, only a member obtained by metal joining the ceramic substrate and the first cooling substrate to each other is replaced, and the second cooling substrate in which the refrigerant flow path is formed can be reused as it is. Accordingly, a manufacturing cost of the wafer placement table can be reduced.

Although the present invention is described with the terms such as up/down, left/right, and front/rear in some cases herein, the terms up/down, left/right, and front/rear only refer to relative positional relationships. Accordingly, when the orientation of the wafer placement table is changed, up/down may be changed to left/right or left/right may be changed to up/down. However, these cases are also included in the technical scope of the present invention.

[2] In the above-described wafer placement table (the wafer placement table described in [1] above), a thermal resistance of the heat dissipation sheet may be smaller than or equal to 0.35 K·cm²/W. In this way, the heat of the first cooling substrate is more quickly transferred to the second cooling substrate, and accordingly, the efficiency of cooling the wafer is further improved.

[3] In the above-described wafer placement table (the wafer placement table described in [1] or [2] above), a Young's modulus of the heat dissipation sheet may be smaller than or equal to 100 MPa. As the Young's modulus of the heat dissipation sheet reduces, a fastening force of the screw member is more uniformly transferred throughout the heat dissipation sheet. Accordingly, the heat dissipation sheet is firmly in close contact with the first cooling substrate and the second cooling substrate. Thus, the efficiency of cooling the wafer is further improved.

[4] In the above-described wafer placement table (the wafer placement table described in any one of [1] to [3] above), a plurality of the screw holes may be provided, and a center-to-center distance between two screw holes adjacent to each other may be smaller than or equal to 100 mm. In this way, the first cooling substrate and the second cooling substrate can be more tightly fastened to each other, and the heat dissipation sheet is firmly in close contact with the first cooling substrate and the second cooling substrate. Accordingly, the efficiency of cooling the wafer is further improved.

[5] In the above-described wafer placement table (the wafer placement table described in any one of [1] to [4] above), a depth of the screw hole may be smaller than or equal to 1.5 times a nominal diameter of the screw member. In this way, the thickness of the first cooling substrate can be reduced. Thus, a heat transfer distance from the lower surface of the ceramic substrate to the upper surface of the second cooling substrate can be reduced. Accordingly, the efficiency of cooling the wafer can be further improved.

[6] In the above-described wafer placement table (the wafer placement table described in any one of [1] to [5] above), a thickness of the first cooling substrate may be greater than or equal to 4 mm and smaller than or equal to 8 mm. When the thickness of the first cooling substrate is greater than or equal to 4 mm, warpage of the first cooling substrate is suppressed, and the heat dissipation sheet is firmly in close contact with the first cooling substrate and the second cooling substrate. Thus, the efficiency of cooling the wafer is further improved. Furthermore, when the thickness of the first cooling substrate is smaller than or equal to 8 mm, the heat transfer distance from the lower surface of the ceramic substrate to the upper surface of the second cooling substrate is short. Accordingly, the efficiency of cooling the wafer can be further improved.

[7] In the above-described wafer placement table (the wafer placement table described in any one of [1] to [6] above), the second cooling substrate may be formed of an easy-to-process material. In this way, the refrigerant flow path can be easily formed in the second cooling substrate, and accordingly, a processing cost can be reduced.

### BRIEF DESCRIPTION OF THE DRAWINGS

FIG. 1 is a vertical cross-sectional view of a wafer placement table 10 installed in a chamber 94.

FIG. 2 is a plan view of the wafer placement table 10.

FIG. 3 is a sectional view of the wafer placement table 10, cut by a horizontal plane passing through a refrigerant flow path 35 seen from above.

FIGS. 4A to 4F are manufacturing step diagrams of the wafer placement table 10 (manufacturing steps of an upper substrate 20).

FIGS. 5A to 5D are manufacturing step diagrams of the wafer placement table 10 (manufacturing steps of a second cooling substrate 30).

FIGS. 6A and 6B are manufacturing step diagrams of the wafer placement table 10 (assembly steps of the wafer placement table 10).

FIG. 7 is a vertical cross-sectional view of a wafer placement table 110 installed in the chamber 94.

### DETAILED DESCRIPTION OF THE INVENTION

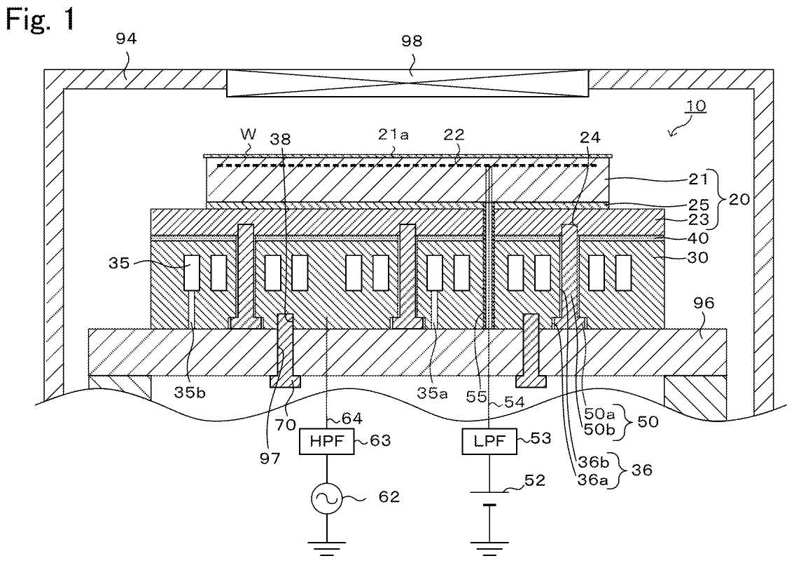

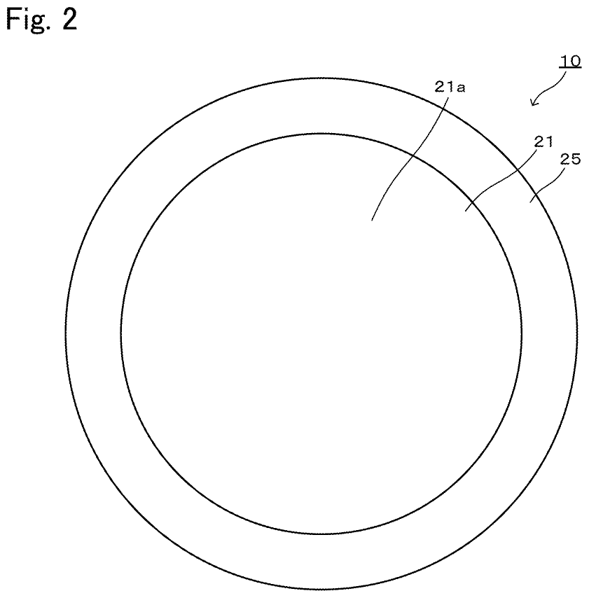

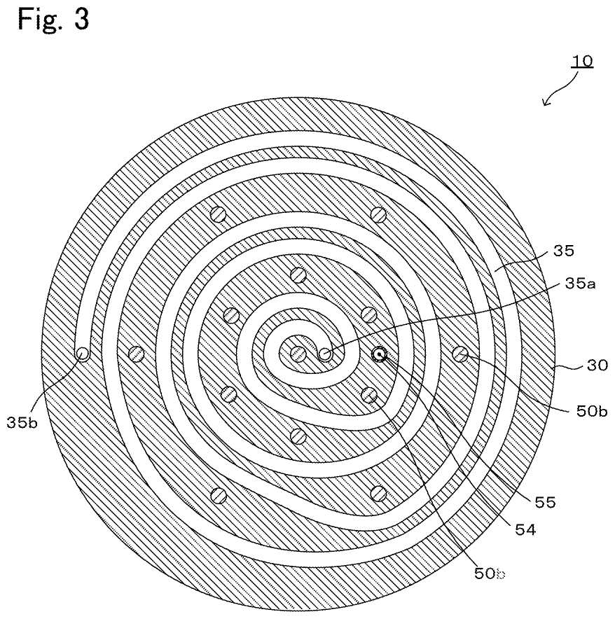

A preferred embodiment of the present invention is described below with reference to the drawings. FIG. 1 is a vertical cross-sectional view of a wafer placement table 10 installed in a chamber 94 (a sectional view taken along a plane including the central axis of the wafer placement table 10). FIG. 2 is a plan view of the wafer placement table 10. FIG. 3 is a sectional view of the wafer placement table 10, seen from above, taken along a horizontal plane passing through a refrigerant flow path 35. Herein, “-” indicating a range of numeric values is used to mean that the numeric values described before and after the “-” are included in the range as the lower limit value and the upper limit value.

The wafer placement table 10 is used to perform CVD, etching, or the like on a wafer W by utilizing plasma and secured to an installation plate 96 provided in the chamber 94 for semiconductor processing. The wafer placement table 10 includes a ceramic substrate 21, a first cooling substrate 23, a metal joining layer 25, a second cooling substrate 30, a heat dissipation sheet 40, and screw members 50. Hereinafter, a member formed by joining the ceramic substrate 21 and the first cooling substrate 23 with the metal joining layer 25 is also referred to as an upper substrate 20.

The upper substrate 20 includes the ceramic substrate 21, the first cooling substrate 23, and the metal joining layer 25 that joins a lower surface of the ceramic substrate 21 and an upper surface of the first cooling substrate 23 to each other. In considering the strength, it is preferable that the thickness of the upper substrate 20 be greater than or equal to 8 mm or greater than or equal to 10 mm. In considering cooling efficiency, it is preferable that the thickness of the upper substrate 20 be smaller than or equal to 25 mm.

The ceramic substrate 21 includes a circular wafer placement surface 21a. A wafer W is to be placed on the wafer placement surface 21a. The ceramic substrate 21 is formed of a ceramic material typical examples of which include alumina, aluminum nitride, and so forth.

The ceramic substrate 21 includes a wafer attraction electrode 22 therein on the side close to the wafer placement surface 21a. The wafer attraction electrode 22 is formed of, for example, a material containing W, Mo, WC, MoC, or the like. The wafer attraction electrode 22 is a monopolar electrostatic electrode having a disc shape or a mesh shape. A layer in the ceramic substrate 21 on the upper side of the wafer attraction electrode 22 functions as a dielectric layer. A wafer attraction direct-current power source 52 is connected to the wafer attraction electrode 22 via a power supply terminal 54. The power supply terminal 54 is provided so as to reach the wafer attraction electrode 22 from the lower surface of the ceramic substrate 21 through an insulation pipe 55 disposed in a through hole that extends, in the up-down direction, through the second cooling substrate 30, the heat dissipation sheet 40, the first cooling substrate 23, and the metal joining layer 25. A low-pass filter (LPF) 53 is provided between the wafer attraction direct-current power source 52 and the wafer attraction electrode 22.

The first cooling substrate 23 is the next larger size disc than the ceramic substrate 21 and fabricated from a composite material of metal and ceramic (may also be referred to as a metal-ceramic composite) or a low thermal expansion metal material. Examples of the metal-ceramic composite material include a metal matrix composite (MMC), a ceramic matrix composite (CMC), and the like. Specific examples of such a metal-ceramic composite include, for example, a material containing Si, SiC, and Ti, a material formed by impregnating a SiC porous material with Al, Si, or Al and Si. The material containing Si, SiC and Ti is referred to as SiSiCTi, the material formed by impregnating the SiC porous material with Al is referred to as AlSiC, and the material formed by impregnating the SiC porous material with Si is referred to as SiSiC. Specific examples of the low thermal expansion metal material include Mo and the like. The absolute value of the difference in coefficient of linear thermal expansion between the material used for the first cooling substrate 23 and the material used for the ceramic substrate 21 at 40-400° C. is preferably smaller than or equal to 1.5×10⁻⁶/K, more preferably smaller than or equal to 1.0×10⁻⁶/K, still more preferably smaller than or equal to 0.5×10⁻⁶/K. From the viewpoint of improving efficiency of cooling the wafer W, the material used for the first cooling substrate 23 preferably has a high thermal conductivity. The thermal conductivity of the material used for the first cooling substrate 23 is, for example, preferably greater than or equal to 50 W/(m·K), more preferably greater than or equal to 70 W/(m·K), still more preferably greater than or equal to 80 W/(m·K). From the viewpoints of obtaining the function as a cooling substrate, the strength, and the stiffness, the thickness of the first cooling substrate 23 is, for example, preferably greater than or equal to 3 mm, more preferably greater than or equal to 4 mm. From the viewpoints of reducing a heat transfer distance between the lower surface of the ceramic substrate 21 and an upper surface of the second cooling substrate 30, the thickness of the first cooling substrate 23 is preferably smaller than or equal to 20 mm, more preferably smaller than or equal to 10 mm, still more preferably smaller than or equal to 8 mm.

A plurality of screw holes 24 open in a lower surface of the first cooling substrate 23. Herein, the screw holes 24 are provided at a single position at the center of the first cooling substrate 23, at six positions which are radially outside the center and equally spaced in a circumferential direction of the first cooling substrate 23, and at six positions which are formed yet radially outside and equally spaced in the circumferential direction of the first cooling substrate 23. However, this is not limiting. Furthermore, herein, the screw holes 24 are formed by providing cylindrical holes in the lower surface of the first cooling substrate 23 and forming thread grooves (not illustrated) in the cylindrical holes. However, this is not limiting. For example, the screw holes 24 may be formed by inserting helical threaded inserts into the cylindrical holes or may be formed by inserting female-threaded terminals (for example, cap nuts or the like) into the cylindrical holes and brazing/soldering the terminals. Although the depth of the screw holes 24 is not particularly limited, the depth may be smaller than or equal to twice a nominal diameter of the screw members 50 or smaller than or equal to 1.5 times the nominal diameter of the screw members 50. In this way, the thickness of the first cooling substrate 23 can be reduced. From the viewpoint of sufficiently generating axial forces of the screw members 50, the depth of the screw holes 24 is preferably greater than or equal to one time of the nominal diameter of the screw members 50. Although the center-to-center distance between two adjacent screw holes 24 is not particularly limited, for example, this distance is preferably smaller than or equal to 100 mm. In this way, the first cooling substrate 23 and the second cooling substrate 30 can be tightly fastened to each other with the screw members 50, leading to improvement of the thermal conductivity of the heat dissipation sheet 40. The center-to-center distance between two adjacent screw holes 24 may be, for example, greater than or equal to 50 mm. The screw holes 24 are preferably disposed in the lower surface of the first cooling substrate 23 at a rate of 150 holes/m² and more preferably 200 holes/m². In this way, the first cooling substrate 23 and the second cooling substrate 30 can be more tightly fastened to each other with the screw members 50, leading to improvement of the thermal conductivity of the heat dissipation sheet 40. It is sufficient that the screw holes 24 open in the lower surface of the first cooling substrate 23. The screw holes 24 may be blind holes as illustrated in FIG. 1 or through holes that extend through the lower surface to upper surface of the first cooling substrate 23.

The metal joining layer 25 joins the lower surface of the ceramic substrate 21 and the upper surface of the first cooling substrate 23 to each other. The metal joining layer 25 may be a layer formed of, for example, solder or a metal brazing alloy. The metal joining layer 25 is formed by, for example, thermal compression bonding (TCB). The TCB refers to a known method in which a metal joining material is interposed between two members to be joined to each other, and pressure is applied to the two members to join the two members to each other in a state in which the metal joining material is heated to a temperature lower than or equal to the solidus temperature of the metal joining material.

The second cooling substrate 30 is a disc member formed of an easy-to-process material. The outer diameter of the second cooling substrate 30 is the same as the outer diameter of the first cooling substrate 23. The refrigerant flow path 35 is provided in the second cooling substrate 30. The refrigerant flow path 35 is provided in a one-stroke pattern to form a helical shape from an inlet 35a to an outlet 35b so as to distribute the refrigerant throughout a region where the ceramic substrate 21 is disposed (FIG. 3). The inlet 35a and the outlet 35b of the refrigerant flow path 35 extend from the lower surface of the second cooling substrate 30 to a bottom surface of the refrigerant flow path 35. The inlet 35a and the outlet 35b of the refrigerant flow path 35 are connected to a refrigerant cooling device (not illustrated). The refrigerant discharged from the outlet 35b undergoes temperature adjustment performed by the refrigerant cooling device, and then, is returned again to the inlet 35a so as to be supplied into the refrigerant flow path 35. The refrigerant flowing through the refrigerant flow path 35 is preferably a liquid and preferably has an electrical insulation property. Examples of a liquid having an electrical insulation property include, for example, a fluorinated inert liquid and the like. The thickness of part of the second cooling substrate 30 on the upper side of the refrigerant flow path 35 may be, for example, greater than or equal to 1 mm or greater than or equal to 2 mm from the viewpoint of improving the strength of this part and may be, for example, smaller than or equal to 10 mm or smaller than or equal to 5 mm from the viewpoint of reducing a heat transfer distance from the upper surface of the second cooling substrate 30 to the refrigerant flow path 35.

The easy-to-process material used for the second cooling substrate 30 is preferably more easily processed than the first cooling substrate 23. As an index of processability, for example, the machinability index described in JIS B 0170(2020) can be used. As the easy-to-process material, a material the machinability index of which is greater than or equal to 40 is preferable, a material the machinability index of which is greater than or equal to 100 is more preferable, a material the machinability index of which is greater than or equal to 140 is still more preferable. Examples of the easy-to-process material include, for example, aluminum, an aluminum alloy, stainless steel (SUS material), and the like. From the viewpoint of improving the efficiency of cooling the wafer W, the material used for the second cooling substrate 30 preferably has a high thermal conductivity. The thermal conductivity of the material used for the second cooling substrate 30 is, for example, preferably greater than or equal to 80 W/(m·K), more preferably greater than or equal to 100 W/(m·K), preferably greater than or equal to 150 W/(m·K).

The second cooling substrate 30 is connected to an RF power source 62 via a power supply terminal 64. Accordingly, the second cooling substrate 30 also functions as a radio-frequency (RF) electrode for generating plasma. A high-pass filter (HPF) 63 is disposed between the second cooling substrate 30 and the RF power source 62.

The second cooling substrate 30 has a plurality of through holes 36. The through holes 36 are provided at positions facing the screw holes 24 and extend through the second cooling substrate 30 in the up-down direction. The through holes 36 are stepped holes in each of which a lower side has a large diameter and an upper side has a small diameter. Each through hole 36 has a large diameter portion 36a that accommodates a head portion 50a of a corresponding one of the screw members 50 and a small diameter portion 36b that allows passage of a shank portion 50b of the screw member 50 therethrough and does not allow passage of the head portion 50a of the screw member 50 therethrough.

The heat dissipation sheet 40 is a circular sheet disposed between the lower surface of the first cooling substrate 23 and the upper surface of the second cooling substrate 30. The heat dissipation sheet 40, which is interposed between the first cooling substrate 23 and the second cooling substrate 30, is compressed in the up-down direction. In this way, the heat dissipation sheet 40 is firmly in close contact with the lower surface of the first cooling substrate 23 and the upper surface of the second cooling substrate 30. Thus, the heat of the first cooling substrate 23 is quickly transferred to the second cooling substrate 30. The thermal resistance of the heat dissipation sheet 40 is more preferably smaller than or equal to 0.35 K·cm²/W, preferably smaller than or equal to 0.1 K·cm²/W. In this way, the efficiency of cooling the wafer W can be further improved. Furthermore, the thermal conductivity of the heat dissipation sheet 40 is preferably greater than or equal to 3 W/(m·K), more preferably greater than or equal to 10 W/(m·K). In this way, the efficiency of cooling the wafer W can be further improved. The thermal resistance and the thermal conductivity of the heat dissipation sheet 40 are a thermal resistance and a thermal conductivity in the up-down direction in a state in which the heat dissipation sheet 40 is assembled (that is, the heat dissipation sheet 40 is compressed in the up-down direction with a predetermined pressure) and can be measured in accordance with ASTM-D5470. The Young's modulus of the heat dissipation sheet 40 is preferably smaller than or equal to 100 MPa, more preferably smaller than or equal to MPa, still more preferably smaller than or equal to 5 MPa. As the Young's modulus of the heat dissipation sheet reduces, fastening forces of the screw members 50 are more uniformly transferred throughout the heat dissipation sheet 40, and accordingly, the entirety of the heat dissipation sheet 40 is firmly in close contact with the first cooling substrate 23 and the second cooling substrate Thus, the wafer W can be more uniformly cooled. The Poisson's ratio of the heat dissipation sheet 40 is preferably smaller than or equal to 0.4, more preferably smaller than or equal to 0.3, still more preferably smaller than or equal to 0.2. As the Poisson's ratio of the heat dissipation sheet 40 reduces, the fastening forces of the screw members 50 are more uniformly transferred throughout the heat dissipation sheet 40 and become less likely to escape in the transverse direction. Thus, the entirety of the heat dissipation sheet 40 is firmly in close contact with the first cooling substrate 23 and the second cooling substrate 30. Thus, the wafer W can be more uniformly cooled. The Shore hardness (ShoreOO) of the heat dissipation sheet 40 may be greater than or equal to 50 and smaller than or equal to 80. The thickness of the heat dissipation sheet 40 is, for example, preferably greater than or equal to 0.05 mm and smaller than or equal to 1 mm, more preferably greater than or equal to 0.1 mm and smaller than or equal to 0.3 mm.

Specifically, the heat dissipation sheet 40 preferably includes carbon and resin. Examples of the carbon include graphite, a carbon fiber, a carbon nanotube, and the like. Examples of the resin include silicone resin and the like. When the carbon is graphite, the carbon is preferably disposed so that a surface direction of graphene included in the graphite extends in the up-down direction. When the carbon is a carbon fiber or a carbon nanotube, the carbon is preferably disposed so that the axial direction extends in the up-down direction. As the material of the heat dissipation sheet 40, for example, a thermal interface material (TIM) can be used. Specific examples of the heat dissipation sheet 40 include, for example, EX20000C9 series and EX20000C4S series (both are made by Dexerials Corporation). The specific examples of the heat dissipation sheet 40 also include, for example, GraphitePAD and GraphiteTIM (registered trademark) (both are made by Panasonic Industry Co., Ltd.).

The screw members 50 have the head portions 50a having a large diameter and the shank portions 50b having a small diameter. The screw members 50 are inserted into the through holes 36 from the lower surface of the second cooling substrate 30 and screwed into the screw holes 24 of the first cooling substrate 23. The head portions 50a of the screw members 50 are accommodated in the large diameter portions 36a so that the head portions 50a do not project downward from the lower surface of the second cooling substrate 30. When the screw members 50 are screwed into the screw holes 24, the first cooling substrate 23 and the second cooling substrate 30 are fastened to each other with the heat dissipation sheet 40 interposed therebetween. Thus, the heat dissipation sheet 40 is compressed in the up-down direction. The material of the screw members 50 is preferably a material exhibiting a good electrical conductivity and a good thermal conductivity. For example, stainless steel is a preferable as the material of the screw members 50. The nominal diameter of the screw members 50 may be, for example, greater than or equal to 3 mm and smaller than or equal to 10 mm, greater than or equal to 4 mm and smaller than or equal to 8 mm, or greater than or equal to 4 mm and smaller than or equal to 5 mm.

Furthermore, a side surface (outer circumferential surface) of the metal joining layer 25, the upper surface and a side surface of the first cooling substrate 23, and a side surface of the second cooling substrate 30 may be coated with an insulation film according to need. Examples of the insulation film include a spray deposit such as, for example, alumina, yttria, and the like.

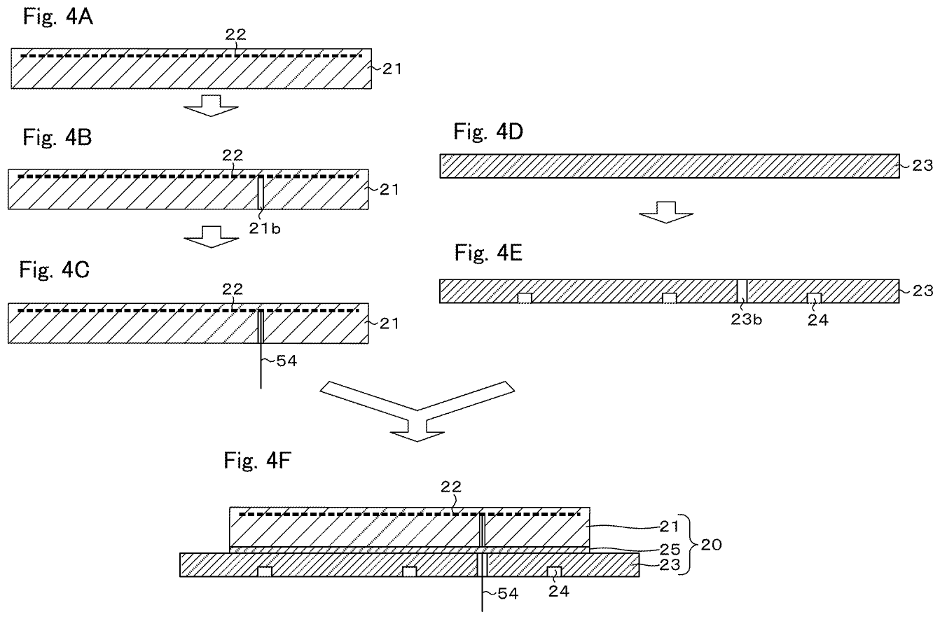

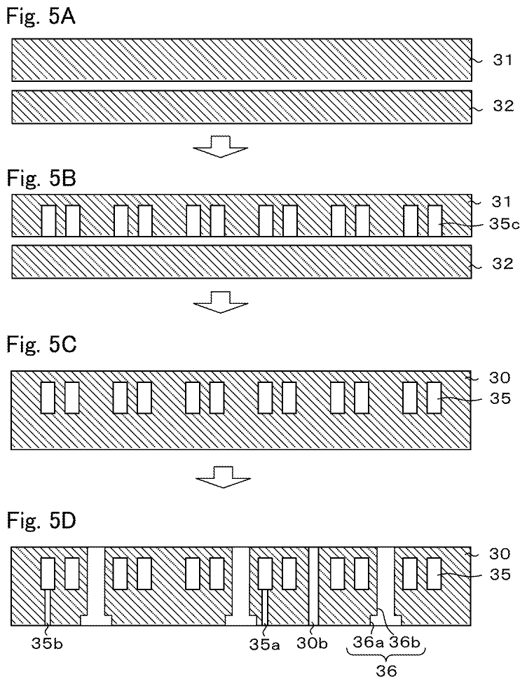

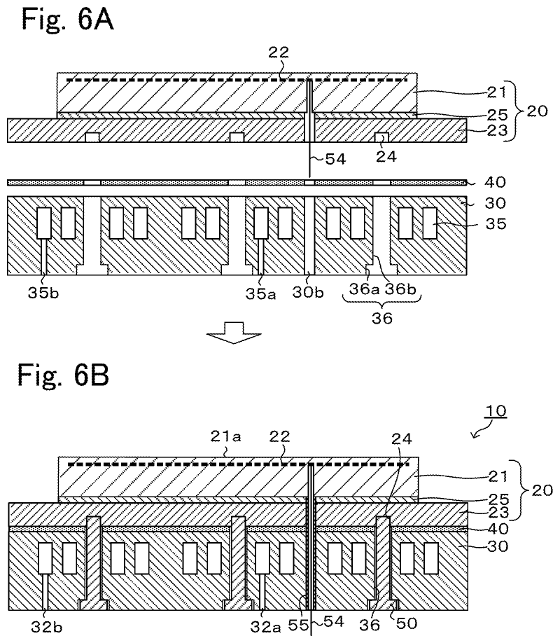

Next, an example of the manufacture of the wafer placement table 10 is described with reference to FIGS. 4-6. FIGS. 4-6 are manufacturing step diagrams of the wafer placement table 10. FIGS. 4A to 4F illustrate manufacturing steps of the upper substrate 20. FIGS. 5A to 5D illustrate manufacturing steps of the second cooling substrate 30. FIGS. 6A and 6B illustrate assembly steps of the wafer placement table 10.

The upper substrate 20 is fabricated, for example, as follows. First, the ceramic substrate 21 is fabricated by performing hot-press firing on a molded body of ceramic powder (FIG. 4A). The ceramic substrate 21 includes the wafer attraction electrode 22 therein. Next, a hole 21b is formed from the lower surface of the ceramic substrate 21 to the wafer attraction electrode 22 (FIG. 4B), and the power supply terminal 54 is inserted into the hole 21b to join the power supply terminal 54 and the wafer attraction electrode 22 to each other (FIG. 4C).

In parallel to this, the first cooling substrate 23 having a disc shape is fabricated (FIG. 4D), a through hole 23b that extends through the first cooling substrate 23 in the up-down direction is formed, and the screw holes 24 is formed at predetermined positions of the lower surface of the first cooling substrate 23 (FIG. 4E). When the ceramic substrate 21 is formed of alumina, the first cooling substrate 23 is preferably formed of SiSiCTi or AlSiC. The reason for this is that, when the first cooling substrate 23 is formed of SiSiCTi or AlSiC, the coefficient of thermal expansion can be substantially the same as that of the alumina.

The first cooling substrate 23 formed of SiSiCTi can be fabricated, for example, as follows. First, a powder mixture is fabricated by mixing together silicon carbide, metal Si, and metal Ti. Next, a molded body having a disc shape is fabricated by causing the obtained powder mixture to undergo uniaxial pressure molding, and the first cooling substrate 23 formed of SiSiCTi is obtained by causing the fabricated molded body to undergo hot-press sintering under an inert atmosphere.

Next, a metal joining material is disposed on the upper surface of the first cooling substrate 23. The metal joining material is provided with a through hole communicating with the through hole 23b of the first cooling substrate 23. Then, the ceramic substrate 21 is placed on the metal joining material while the power supply terminal 54 of the ceramic substrate 21 is being inserted into the through hole 23b of the first cooling substrate 23. In this way, a layered body formed by stacking the first cooling substrate 23, the metal joining material, and the ceramic substrate 21 in this order from below is obtained. When this layered body is pressurized while being heated (TCB), the upper substrate 20 is obtained (FIG. 4F). The upper substrate 20 is obtained by joining the ceramic substrate 21 to the upper surface of the first cooling substrate 23 with the metal joining layer 25 interposed therebetween.

The TCB is performed, for example, as follows. That is, the layered body is pressed and joined together at a temperature lower than or equal to the solidus temperature of the metal joining material (for example, at a temperature between a temperature higher than or equal to a temperature calculated by subtracting 20° C. from the solidus temperature and a temperature lower than or equal to the solidus temperature), and after that, the temperature is returned to room temperature. In this way, the metal joining material is formed into the metal joining layer (or an electrically conductive joining layer). As the metal joining material at this time, an Al—Mg based joining body or an Al—Si—Mg based joining body may be used. For example, when the TCB is performed with the Al—Si—Mg based joining body, the layered body is pressurized in a heated state under a vacuum atmosphere. The thickness of the metal joining material to be used is preferably about 100 μm.

The second cooling substrate 30 is fabricated, for example, as follows. First, two disc members 31 and 32 from which the second cooling substrate 30 is made, which have a disc shape, and which are formed of an easy-to-process material are prepared (FIG. 5A). The disc members 31 and 32 are preferably formed of aluminum, an aluminum alloy, or stainless steel. Next, a groove 35c, which is finally becomes the refrigerant flow path 35, is formed in a lower surface of the upper disc member 31 (FIG. 5B). After that, the lower surface of the upper disc member 31 and an upper surface of the lower disc member 32 are joined to each other with a joining material (not illustrated, for example, a brazing alloy or the like) to fabricate the second cooling substrate 30 (FIG. 5C). Then, the inlet 35a and the outlet 35b that extend, in the up-down direction, from the lower surface of the second cooling substrate 30 to the bottom surface of the refrigerant flow path 35 are formed, and a terminal hole 30b that extends, in the up-down direction, through the second cooling substrate 30 is formed. Furthermore, the through holes 36 that each have the large diameter portion 36a and the small diameter portion 36b are formed at predetermined positions of the second cooling substrate 30 (FIG. 5D).

The wafer placement table 10 is fabricated by fastening together, with the screw members 50, the upper substrate 20 and the second cooling substrate 30 that have been fabricated as described above. Specifically, first, as illustrated in FIG. 6A, the heat dissipation sheet 40 is disposed on the upper surface of the second cooling substrate 30. The heat dissipation sheet 40 is a circular sheet having the same diameter as that of the first cooling substrate 23. Next, the upper substrate 20 is placed on the heat dissipation sheet 40 disposed on the upper surface of the second cooling substrate while the power supply terminal 54 of the upper substrate 20 is being inserted into the terminal hole 30b. Next, the screw members 50 are inserted into the through holes 36 from the lower surface of the second cooling substrate 30 and screwed into the screw holes 24 of the first cooling substrate 23. In this way, the heat dissipation sheet 40 is compressed between the first cooling substrate 23 and the second cooling substrate 30, thereby exhibiting high thermal conduction performance. After that, the insulation pipe 55, which allows the power supply terminal 54 to be inserted therethrough, is disposed in the terminal hole 30b (FIG. 6B). In the way as described above, the wafer placement table 10 can be obtained.

Next, an example of use of the wafer placement table 10 is described with reference to FIG. 1. First, the wafer placement table 10 is installed on the installation plate 96 of the chamber 94. Next, screw members 70 are screwed into screw holes 38 provided in the lower surface of the second cooling substrate 30 through screw insertion holes 97 from a lower surface of the installation plate 96. In this way, the wafer placement table 10 is secured to the installation plate 96 with the screw members 70.

The wafer W having a disc shape is placed on the wafer placement surface 21a of the wafer placement table 10 installed on the installation plate 96. In this state, a direct-current voltage of the wafer attraction direct-current power source 52 is applied to the wafer attraction electrode 22 to cause the wafer W to be attracted to the wafer placement surface 21a. Furthermore, the refrigerant having undergone the temperature adjustment is supplied to the inlet 35a of the refrigerant flow path 35, and the refrigerant is discharged from the outlet 35b of the refrigerant flow path 35. Then, the inside of the chamber 94 is set so as to obtain a predetermined vacuum atmosphere (or a predetermined decompressed atmosphere), and an RF voltage is applied to the second cooling substrate 30 from the RF power source 62 while the process gas is being supplied from a shower head 98. As a result, plasma is generated between the wafer W and the shower head 98. By utilizing the plasma, a CVD film formation or etching is performed on the wafer W.

With the above-described wafer placement table 10, the efficiency of cooling the wafer W is high due to joining of the ceramic substrate 21 and the first cooling substrate 23 to each other with the metal joining layer 25. In addition, the first cooling substrate 23 and the second cooling substrate 30 are fastened to each other with the screw members 50, and the heat dissipation sheet 40 is disposed between the first cooling substrate 23 and the second cooling substrate 30. The heat dissipation sheet 40 is firmly in close contact with the first cooling substrate 23 and the second cooling substrate 30 by fastening the first cooling substrate 23 and the second cooling substrate to each other with the screw members 50. Thus, the heat of the first cooling substrate 23 is quickly transferred to the second cooling substrate 30. Accordingly, the efficiency of cooling the wafer W is high. Furthermore, the first cooling substrate 23 and the second cooling substrate are joined to each other with the screw members 50. Thus, when the ceramic substrate 21 degrades due to use of the wafer placement table 10, only the upper substrate 20 that is a member obtained by metal joining the ceramic substrate 21 and the first cooling substrate 23 to each other is replaced, and the second cooling substrate 30 in which the refrigerant flow path 35 is formed can be reused as it is. Accordingly, a manufacturing cost of the wafer placement table can be reduced.

Furthermore, the thermal resistance of the heat dissipation sheet 40 is preferably smaller than or equal to 0.35 K·cm²/W. In this way, the heat of the first cooling substrate 23 is more quickly transferred to the second cooling substrate 30, and accordingly, the efficiency of cooling the wafer W is further improved. To obtain such thermal resistance, the pressure to compress the heat dissipation sheet 40 in the up-down direction is preferably, for example, greater than or equal to 0.05 MPa or greater than or equal to 0.2 MPa. In this way, the heat dissipation sheet 40 is firmly in close contact with the first cooling substrate 23 and the second cooling substrate 30, and accordingly, the thermal resistance of the heat dissipation sheet 40 can be reduced. From the viewpoint of suppressing breakage of the heat dissipation sheet 40, the pressure to compress the heat dissipation sheet 40 in the up-down direction is preferably, for example, smaller than or equal to 0.6 MPa or smaller than or equal to 0.55 MPa. Meanwhile, the pressure to compress the heat dissipation sheet 40 in the up-down direction tends to reduce as the distance from the screw members 50 increases, and this pressure varies in an in-plane direction. When this variation in pressure [MPa] is evaluated as a pressure variation [-] obtained by dividing the variation in pressure by bearing stress [MPa] applied to the heat dissipation sheet 40 when the axial forces of the screw members 50 are assumed to be uniformly applied to the heat dissipation sheet 40, the pressure variation is preferably smaller than or equal to 2.0, more preferably smaller than or equal to 1.7, and still more preferably smaller than or equal to 1.0. The pressure variation can be reduced as the Young's modulus of the heat dissipation sheet 40 reduces, and the pressure variation can be reduced as the center-to-center distance between the screw holes 24 reduces. Meanwhile, when the center-to-center distance between the screw holes 24 is attempted to reduce to reduce the pressure variation, a large number of screw holes 24 is required and disposition of the screw holes 24 may become difficult. According to a simulation, in the case where the Young's modulus of the heat dissipation sheet 40 is smaller than or equal to 80 MPa, by setting the center-to-center distance between the screw holes 24 to smaller than or equal to 70 mm, the pressure variation becomes smaller than or equal to 2.0, and by setting the center-to-center distance between the screw holes 24 to smaller than or equal to 55 mm, the pressure variation becomes smaller than or equal to 1.0. Furthermore, in the case where the Young's modulus of the heat dissipation sheet 40 is smaller than or equal to 10 MPa, the pressure variation becomes about 1 even when the center-to-center distance between the screw holes 24 is set to 100 mm. As described above, from the view point of reducing the pressure variation without excessively reducing the center-to-center distance between the screw holes 24, the Young's modulus of the heat dissipation sheet 40 is preferably smaller than or equal to 80 MPa, more preferably smaller than or equal to 10 MPa. The number and disposition of the screw holes 24 are preferably set by considering the pressure variation in addition to the required pressure to compress the heat dissipation sheet 40.

Furthermore, the second cooling substrate 30 is formed of an easy-to-process material. In this way, the refrigerant flow path 35 can be easily formed in the second cooling substrate 30, and accordingly, a processing cost can be reduced. Furthermore, compared to the case where the second cooling substrate 30 is formed of a composite material of metal and ceramic (for example, MMC or CMC), a material cost can be reduced to a lower value.

The heat dissipation sheet 40 has an electrical conductivity. In this way, the second cooling substrate 30 has the same potential as that of the first cooling substrate 23 and the metal joining layer 25. Thus, the first cooling substrate 23 and the metal joining layer 25 can be used as the RF electrode, and accordingly, plasma can be easily generated above the wafer W. The screw members 50 can be electrically conductive so as to cause the second cooling substrate 30 and the first cooling substrate 23 to have the same potential through the screw members 50.

Of course, the present invention is not in any way limited to the above-described embodiment, and the present invention can be carried out in a variety of forms as long as the forms belong to the technical scope of the present invention.

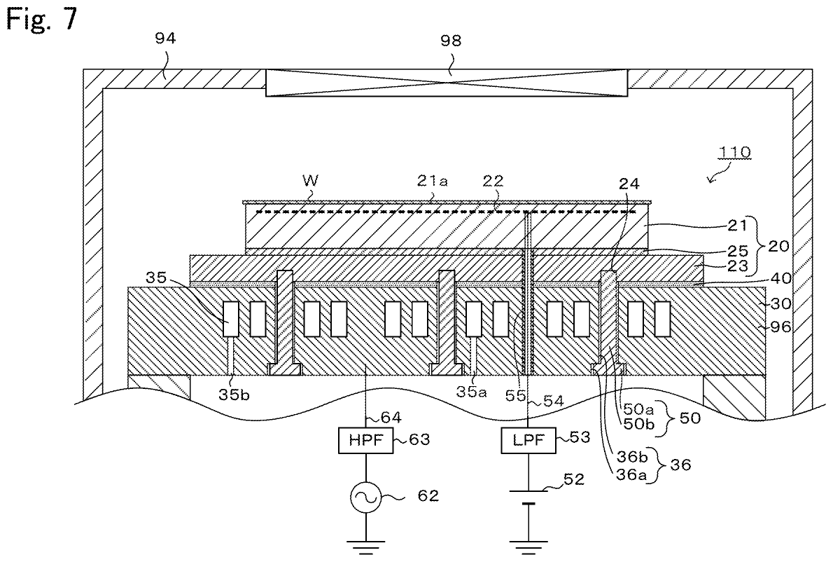

Although the wafer placement table 10 in which the first cooling substrate 23 and the second cooling substrate 30 are fastened to each other with the screw members 50 is installed on the installation plate 96 of the chamber 94 according to the above-described embodiment, this is not limiting. For example, as is the case with a wafer placement table 110 illustrated in FIG. 7, the second cooling substrate 30 may also be used as the installation plate 96 of the chamber 94. In FIG. 7, the same elements as those in the above-described embodiment are denoted by the same reference numerals.

Although the example in which the heat dissipation sheet 40 is electrically conductive is indicated according to the above-described embodiment, the heat dissipation sheet 40 may be insulative.

Although the wafer attraction electrode 22 is included in the ceramic substrate 21 according to the above-described embodiment, instead of or in addition to the wafer attraction electrode 22, the RF electrode for generating plasma may be included in the ceramic substrate 21. In this case, the radio-frequency power source is connected not to the second cooling substrate 30 but to the RF electrode. Also, a heater electrode (resistance heating element) may be included in the ceramic substrate 21. In this case, a heater power source is connected to the heater electrode. As described above, the ceramic substrate 21 may include a single layer of electrode or more than one layer of electrode.

Although the refrigerant flow path 35 is provided in a helical shape from the inlet 35a to the outlet 35b according to the above-described embodiment, the shape of a refrigerant flow path 35 is not particularly limited. Furthermore, although a single refrigerant flow path 35 is provided according to the above-described embodiment, a plurality of refrigerant flow paths 35 may be provided.

Although the diameter of the first cooling substrate 23 is set to be larger than that of the ceramic substrate 21 according to the above-described embodiment, the diameter of the first cooling substrate 23 may be the same as that of the ceramic substrate 21. Furthermore, although the diameter of the second cooling substrate 30 is set to be the same as that of the first cooling substrate 23, the diameter of the second cooling substrate 30 may be larger than that of the first cooling substrate 23.

According to the above-described embodiment, the ceramic substrate 21 is fabricated by performing hot-press firing on a molded body of ceramic powder. This molded body may be fabricated by stacking a plurality of tape molded bodies, performing a mold casting method, or packing the ceramic powder.

Although the second cooling substrate 30 is formed of an easy-to-process material according to the above-described embodiment, a second cooling substrate 30 may be formed of a composite material of metal and ceramic or a low thermal expansion metal material such as molybdenum. In this way, the difference in coefficient of thermal expansion between the second cooling substrate 30 and the upper substrate 20 is small, and accordingly, warpage or breakage of the upper substrate 20 and the second cooling substrate due to thermal stress can be suppressed.

According to the above-described embodiment, a through hole that extends through the wafer placement table from the lower surface of the second cooling substrate 30 to the wafer placement surface 21a may be provided. Examples of such a hole include a gas supply hole through which a thermal conduction gas (for example, He gas) is supplied to the back surface of the wafer W, a lift pin hole through which a lift pin for moving up and down the wafer W relative to the wafer placement surface 21a is inserted, and the like. The thermal conduction gas is supplied to a space formed by the wafer W and many small projections (not illustrated, that support the wafer W) provided on the wafer placement surface 21a.

According to the above-described embodiment, in addition to the heat dissipation sheet 40, a sealing member may be provided between the lower surface of the first cooling substrate 23 and the upper surface of the second cooling substrate 30. The sealing member prevents, for example, the gas supplied to the above-described gas supply hole from leaking to the outside through a gap between the first cooling substrate 23 and the second cooling substrate 30. The sealing property is obtained when the sealing member is compressed in the up-down direction. The sealing member is, for example, a ring formed of metal or resin and disposed an outer circumferential side of the gas supply hole, an outer circumferential side of the lift pin hole, an outer circumferential side of the insulation pipe 55, a slightly inner circumferential side of an outer circumference of the first cooling substrate 23, or the like. The sealing member may be electrically conductive or insulative.

International Application No. PCT/JP2022/025790, filed on Jun. 28, 2022, is incorporated herein by reference in its entirety.

What is claimed is:

1. A wafer placement table comprising:
a ceramic substrate that has a wafer placement surface on an upper surface thereof and that includes an electrode therein;
a first cooling substrate formed of a composite material of metal and ceramic or a low thermal expansion metal material;
a metal joining layer that joins a lower surface of the ceramic substrate and an upper surface of the first cooling substrate to each other;
a second cooling substrate in which a refrigerant flow path is formed;
a heat dissipation sheet disposed between a lower surface of the first cooling substrate and an upper surface of the second cooling substrate;
at least one screw hole that opens in the lower surface of the first cooling substrate;
a through hole that is provided at a position facing the at least one screw hole and that extends through the second cooling substrate in an up-down direction; and
a screw member that is inserted into the through hole from a lower surface of the second cooling substrate and that is screwed into the at least one screw hole.

2. The wafer placement table according to claim 1, wherein
a thermal resistance of the heat dissipation sheet is smaller than or equal to 0.35 K·cm²/W.

3. The wafer placement table according to claim 1, wherein
a Young's modulus of the heat dissipation sheet is smaller than or equal to 100 MPa.

4. The wafer placement table according to claim 1, wherein
the at least one screw hole includes a plurality of screw holes, and a center-to-center distance between two screw holes adjacent to each other is smaller than or equal to 100 mm.

5. The wafer placement table according to claim 1, wherein
a depth of the at least one screw hole is smaller than or equal to 1.5 times a nominal diameter of the screw member.

6. The wafer placement table according to claim 1, wherein
a thickness of the first cooling substrate is greater than or equal to 4 mm and smaller than or equal to 8 mm.

7. The wafer placement table according to claim 1, wherein
the second cooling substrate is formed of an easy-to-process material.
